(19) United States
(12) Patent Application Publication
(10) Pub. No.: US 2016/0218067 A1
(43) Pub. Date: Jul. 28, 2016

(54) SEMICONDUCTOR DEVICE AND METHOD OF MANUFACTURING THE SEMICONDUCTOR DEVICE

(71) Applicant: KABUSHIKI KAISHA TOSHIBA, Tokyo (JP)

(72) Inventors: Shingo MASUKO, Kanazawa Ishikawa (JP); Yoshiharu TAKADA, Nonoichi Ishikawa (JP); Takashi ONIZAWA, Nomi Ishikawa (JP); Yasuhiro ISOBE, Kanazawa Ishikawa (JP); Kohei OASA, Nonoichi Ishikawa (JP)

(21) Appl. No.: 14/840,823

(22) Filed: Aug. 31, 2015

(30) Foreign Application Priority Data
Jan. 23, 2015 (JP) 2015-011277

(51) Int. Cl. H01L 23/00; H01L 21/78; H01L 21/02; H01L 29/20

(52) U.S. Cl. CPC H01L 23/562; H01L 29/2003; H01L 21/78; H01L 21/02142

(57) ABSTRACT

A semiconductor device includes a substrate, a nitride semiconductor layer formed on the substrate, and a protection layer, comprising carbon, covering a side surface of the nitride semiconductor layer.

### CROSS-REFERENCE TO RELATED APPLICATION

This application is based upon and claims the benefit of priority from Japanese Patent Application No. 2015-011277, filed Jan. 23, 2015, the entire contents of which are incorporated herein by reference.

### FIELD

Embodiments described herein relate generally to a semiconductor device and a method of manufacturing the semiconductor device. For example, the embodiments relate to a semiconductor device which includes a power semiconductor element and a method of manufacturing the semiconductor device.

### BACKGROUND

A power semiconductor device which includes a power semiconductor element such as a switching element or a diode is used in a circuit of a switching power source, an inverter or the like. A power semiconductor element which is formed using a compound semiconductor such as a nitride semiconductor has excellent material characteristics for power semiconductor devices and hence, a power semiconductor device having high performance may be created.

A semiconductor wafer on which power semiconductor devices are formed is divided into a plurality of semiconductor chips, i.e., the chips are singulated from the wafer, by cutting the wafer in a dicing step. In such a dicing step, there may be a case where chipping or cracks occur in the nitride semiconductor layer. “Chipping” means a breakage which occurs on a dicing surface, and “cracks” or “cracking” means fractures which are formed on the dicing surface continue inwardly of the nitride semiconductor layer to form regions of physical discontinuity therein. Due to such chipping or cracks, there is a possibility that water or the like will intrude into the nitride semiconductor. Further, even when cracks or the like are not formed, there is a possibility that water or the like will intrude into the nitride semiconductor from a side surface of a nitride semiconductor layer. Accordingly, the power semiconductor device may become defective or a yield rate of the power semiconductor device may be lowered if water or the like intrudes into the nitride semiconductor layer.

### DESCRIPTION OF THE DRAWINGS

FIG. 1 is a plan view of a semiconductor device according to a first embodiment.

FIG. 2 is a cross-sectional view of the semiconductor device according to the first embodiment.

FIG. 3 is a cross-sectional view illustrating a manufacturing step of the semiconductor device according to the first embodiment.

FIG. 4 is a cross-sectional view illustrating a manufacturing step of the semiconductor device according to the first embodiment.

FIG. 5 is a cross-sectional view illustrating a manufacturing step of the semiconductor device according to the first embodiment.

FIG. 6 is a cross-sectional view illustrating a manufacturing step of the semiconductor device according to the first embodiment.

FIG. 7 is a cross-sectional view illustrating a manufacturing step of the semiconductor device according to the first embodiment.

FIG. 8 is a cross-sectional view illustrating a manufacturing step of the semiconductor device according to the first embodiment.

FIG. 9 is a cross-sectional view illustrating a manufacturing step of a semiconductor device according to a second embodiment.

FIG. 10 is a cross-sectional view illustrating a manufacturing step of the semiconductor device according to the second embodiment.

FIG. 11 is a cross-sectional view illustrating a manufacturing step of a semiconductor device according to a third embodiment.

FIG. 12 is a cross-sectional view illustrating a manufacturing step of the semiconductor device according to the third embodiment.

### DETAILED DESCRIPTION

According to an embodiment, there is provided a semiconductor device and a method of manufacturing the semiconductor device where the occurrence of a defect therein may be suppressed.

In general, according to one embodiment, a semiconductor device includes: a substrate; a nitride semiconductor layer provided on the substrate; and a first protection layer, comprising carbon, that covers a side surface of the nitride semiconductor layer.

According to another embodiment, a method of manufacturing a semiconductor device including first and second semiconductor chips that respectively include a nitride semiconductor layer and are disposed on a substrate with a gap therebetween is provided, the method including: forming first and second masks respectively on the first and second semiconductor chips; etching the portion of the nitride semiconductor layer located in the gap between the first and second semiconductor chips; modifying side surfaces of the nitride semiconductor layers, exposed by the etching, with a laser beam; and dicing the first and second semiconductor chips along the gap.

Hereinafter, an embodiment is explained by reference to drawing figures. The drawings are schematic or conceptual views and hence, sizes and ratios of the respective parts in the respective drawings are not always equal to those of an actual semiconductor device. The embodiments described hereinafter merely exemplify a device and a method for embodying the technical concept of the present invention, and the technical concept of the present invention is not limited by the shapes, structures, dispositions and the like of the structural parts thereof described in the embodiment. In the explanation made hereinafter, structural elements having the substantially identical functions or configurations are given same symbols, and these structural elements are explained repeatedly only when such explanation is necessary.

### First Embodiment

### [1-1] Configuration of Semiconductor Device

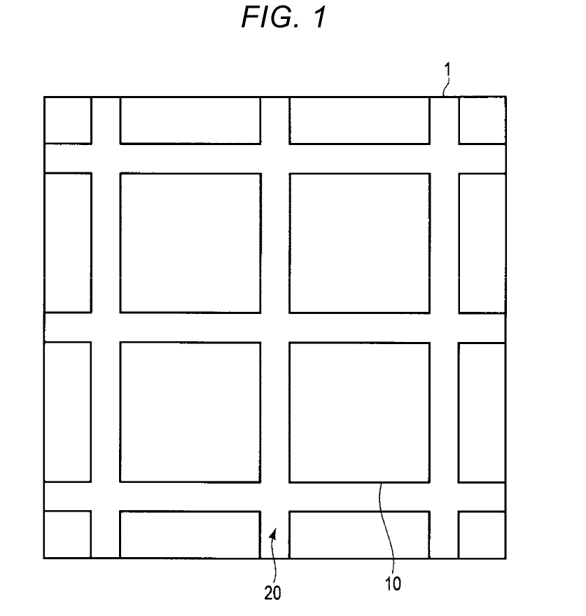

FIG. 1 is a plan view of a semiconductor device 1 according to a first embodiment. The semiconductor device 1 is formed of a semiconductor wafer. FIG. 1 selectively shows a portion of the semiconductor wafer.

The semiconductor device 1 includes a plurality of semiconductor chips 10 disposed in a matrix array, for example. The plurality of semiconductor chips 10 are disposed with dicing lines 20 extending therebetween. The dicing lines 20 are regions along which the plurality of semiconductor chips 10 are separated from one another in a dicing step.

Each semiconductor chip 10 is formed of a power semiconductor device which performs conversion and control of a power source (power), for example. A power semiconductor element which the power semiconductor device includes are a power MOSFET (Metal Oxide Semiconductor Field Effect Transistor), a HEMT (High Electron Mobility Transistor), an HBT (Heterojunction Bipolar Transistor), an IGBT (Insulated Gate Bipolar Transistor), a diode and the like.

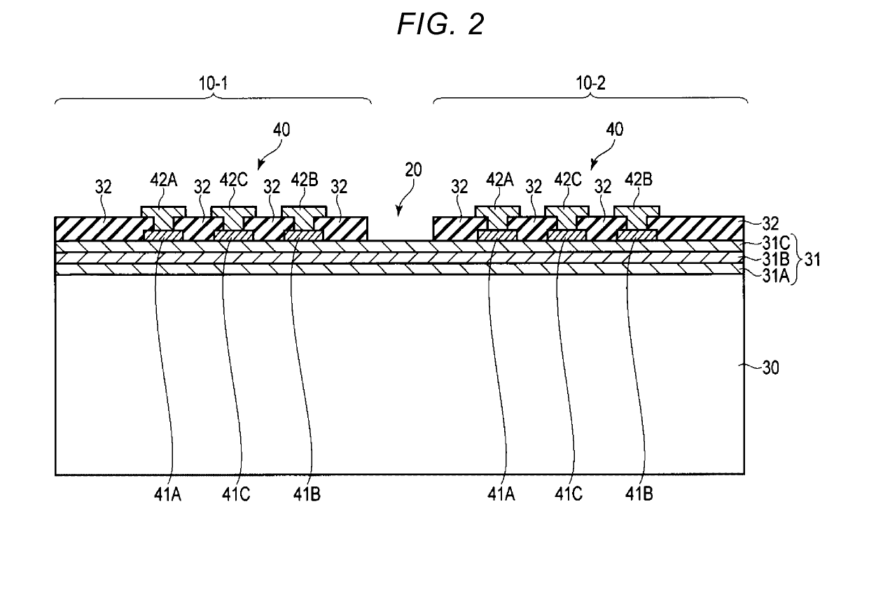

Hereinafter, the explanation is made by taking the semiconductor chip 10 provided with an HEMT as an example. FIG. 2 is a cross-sectional view of the semiconductor device 1.

The semiconductor device 1 includes semiconductor chips 10-1, 10-2. The semiconductor chips 10-1, 10-2 are disposed with the dicing line 20 extending therebetween. In the explanation made hereinafter, when it is not necessary to differentiate the semiconductor chips 10-1, 10-2 from each other, a reference symbol is given by omitting a branch number such as “semiconductor chip 10”. The explanation of the semiconductor chip 10 is applicable to both the semiconductor chips 10-1, 10-2.

The semiconductor chip 10 includes: a substrate 30; a nitride semiconductor layer 31; and a protection layer 32. The nitride semiconductor layer 31 is not divided in correspondence with the respective individual semiconductor chips 10, but is formed in common in the plurality of semiconductor chips 10. The protection layer 32 is individually provided in the individual semiconductor chips 10 at the dicing step, such as by a previous etching step by which it was removed over the dicing lines 20 or removed by cutting therethrough. That is, regions from which the protection layers 32 are removed form the dicing lines 20. The portions of the nitride semiconductor layer 31 which extend across the dicing lines 20 are exposed on an upper surface of the semiconductor device 1.

The substrate 30 is formed of a silicon (Si) substrate where a (111) plane forms a main plane (uppermost surface) thereof, for example. As a material for forming the substrate 30, silicon carbide (SiC), gallium nitride (GaN), gallium phosphide (GaP), indium phosphide (InP), gallium arsenide (GaAs), sapphire (Al₂O₃) or the like may be used.

The nitride semiconductor layer 31 is formed by stacking three layers including a buffer layer 31A, a channel layer 31B and a barrier layer 31C over the substrate 30, for example.

The buffer layer 31A is provided on the substrate 30. The buffer layer 31A has a function of alleviating strain caused by the difference between the lattice constant of a nitride semiconductor layer formed on the buffer layer 31A and the lattice constant of the substrate 30, and also has a function of controlling the crystal structure of the nitride semiconductor layer formed on the buffer layer 31A. The buffer layer 31A is made of Al_{X}G_{a1-X}N (0≦X≦1), for example. The buffer layer 31A may be formed by stacking a plurality of layers of Al_{X}Ga_{1-X}N having different composition ratios. When the buffer layer 31A is formed by adopting such stacking structure, composition ratios of the layers in the stacking structure are adjusted such that lattice constants of a plurality of layers which form the stacking structure are changed from a lattice constant of the layer disposed below the buffer layer 31A to, or close to, the lattice constant of the layer disposed above the buffer layer 31A with respect to the layers which interpose the buffer layer 31A therebetween.

The channel layer 31B is formed on the buffer layer 31A. The channel layer 31B is a layer in which a channel (current path) of a transistor is formed. The channel layer 31B is made of Al_{X}In_{Y}Ga_{1-(X+Y)}N (0≦X<1, 0≦Y<1, 0≦X+Y<1). The channel layer 31B is an undoped layer, and is made of a nitride semiconductor having favorable crystal structure and uniformity of crystal structure (a high-quality nitride semiconductor). “Undoped” means that a layer is not intentionally doped with a dopant. For example, a trace amount of dopant which unintentionally enters the layer during a manufacturing step or the like falls within the meaning of the term “undoped”. In this embodiment, the channel layer 31B is made of undoped GaN (also referred to as intrinsic GaN).

The barrier layer 31C is provided on the channel layer 31B. The barrier layer 31C is made of Al_{X}In_{Y}Ga_{1-(X+Y)}N (0≦X<1, 0≦Y<1, 0≦X+Y<1). The barrier layer 31C is made of a nitride semiconductor having a band gap larger than the channel layer 31B. In this embodiment, the barrier layer 31C is made of undoped AlGaN, for example.

The plurality of semiconductor layers forming the semiconductor device 1 are sequentially formed by epitaxial growth using an MOCVD (Metal Organic Chemical Vapor Deposition) method, for example. That is, the plurality of semiconductor layers forming the semiconductor device 1 are formed of epitaxial layers.

The semiconductor chip 10 includes a HEMT 40. The HEMT 40 is formed of a source electrode 41A, a drain electrode 41B, a gate electrode 41C and a part of the nitride semiconductor layer 31. Electrode pads 42A, 42B and 42C are formed on the source electrode 41A, the drain electrode 41B and the gate electrode 41C, respectively.

The source electrode 41A and the drain electrode 41B are provided on the barrier layer 31C and spaced from one another. The gate electrode 41C is formed on the barrier layer 31C between the source electrode 41A and the drain electrode 41B such that the gate electrode 41C is spaced from the source electrode 41A and from the drain electrode 41B.

The gate electrode 41C and the barrier layer 31C form a Schottky junction. That is, the gate electrode 41C contains a material by which the gate electrode 41C forms a Schottky junction with the barrier layer 31C. The semiconductor device 1 shown in FIG. 2 is a Schottky-barrier HEMT. The gate electrode 41C adopts the stacking structure of Au/Ni, for example. A material on a left side of the “/” is the material forming an upper layer, and the material on a right side of the “/” is the material forming a lower layer.

The semiconductor device 1 is not limited to the Schottky-barrier HEMT, and may be an MIS (Metal Insulator Semiconductor) HEMT where a gate insulating film is interposed between the barrier layer 31C and the gate electrode 41C.

The source electrode 41A and the barrier layer 31C form an ohmic contact with each other. In the same manner, the drain electrode 41B and the barrier layer 31C form an ohmic contact with each other. That is, the source electrode 41A and the drain electrode 41B, respectively contain a material by which the source electrode 41A and the drain electrode 41B form an ohmic contact with the barrier layer 31C. The source electrode 41A and the drain electrode 41B adopt the stacking structure of Al/Ti respectively, for example.

In the heterojunction structure formed of the channel layer 31B and the barrier layer 31C, the lattice constant of the barrier layer 31C is smaller than the lattice constant of the channel layer 31B and hence, strain is generated in the barrier layer 31C. Due to a piezoelectric effect generated by the strain, a piezoelectric polarization is generated in the barrier layer 31C and hence, a two-dimensional electron gas (2DEG) is generated in the vicinity of a boundary of the channel layer 31B with the barrier layer 31C. The two-dimensional electron gas forms a channel between the source electrode 41A and the drain electrode 41B. Due to a Schottky barrier generated by a Schottky junction between the gate electrode 41C and the barrier layer 31C, the drain current may be controlled by the voltage applied to the gate electrode 42C to enlarge or decrease the size of the depletion region in the channel layer 31B.

The protection layer 32 is formed on the nitride semiconductor layer 31 and portions of the electrodes (including the source electrode 41A, the drain electrode 41B and the gate electrode 41C). The protection layer 32 is also referred to as a passivation layer. The protection layer 32 has opening portions for extending the electrode pads 42 A-C into contact with the electrodes 41A-C. The protection layer 32 is made of an insulation material. Silicon nitride (SiN), a silicon oxide (SiO₂) or the like is used as a material for forming the protection layer 32.

The electrode pads 42A, 42B, 42C are used for connecting the semiconductor chip 10 with an external circuit, and are exposed to the outside of the semiconductor chip 10. The electrode pads 42A, 42B, and 42C are electrically connected to the source electrode 41A, the drain electrode 41B and the gate electrode 41C respectively through the opening portions formed in the protection layer 32.

### [1-2] Manufacturing Method

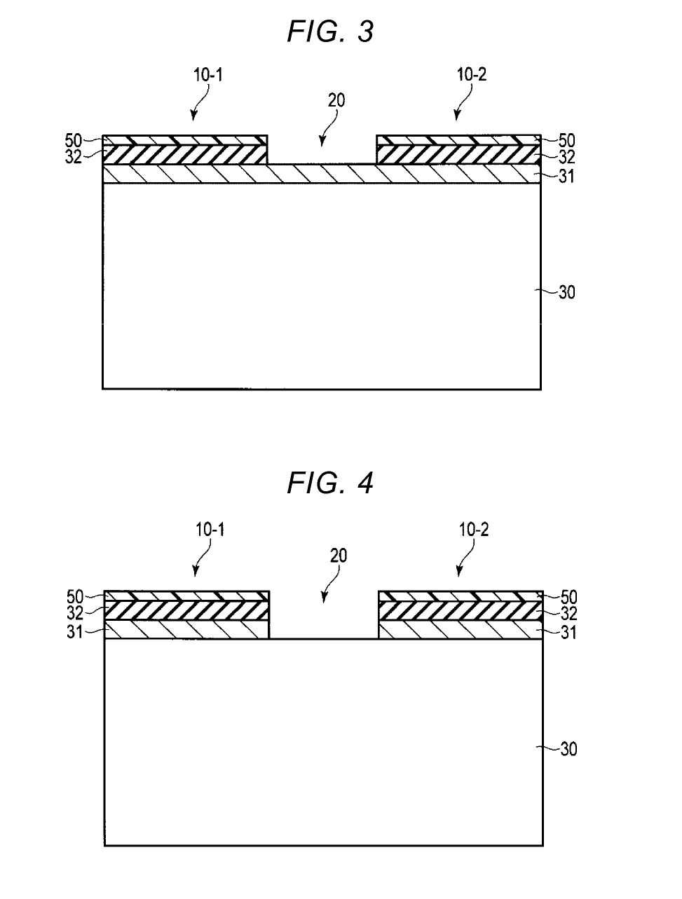

Next, a method of manufacturing the semiconductor device 1 according to the first embodiment is described by reference to FIG. 3 to FIG. 8. In FIG. 3 to FIG. 8, to prevent the drawings from becoming complicated, a nitride semiconductor layer 31 is schematically shown, that is, the nitride semiconductor layer 31 is shown as a single layer. Further, the electrodes and the electrode pads are also omitted in drawing FIG. 3 to FIG. 8.

In FIG. 3 to FIG. 8, one dicing line (cutting region) 20 and portions of two adjacent semiconductor chips 10-1, 10-2 disposed on either side of the dicing line 20 are selectively shown. A width of the dicing line 20 is set to correspond to a width of a blade used in a dicing step or greater, and is set to a value which is more than or equal to 45 μm and less than or equal to 70 μm, for example.

First, a semiconductor device (semiconductor wafer) 1 where a plurality of semiconductor chips 10 are formed on a substrate 30 is prepared. Next, aback surface of the substrate 30 is uniformly ground using a grinding device to reduce the thickness of the substrate 30 to a predetermined thickness. The thickness of the substrate 30 is appropriately set according to the specification of the semiconductor chip 10.

Subsequently, as shown in FIG. 3, a resist (mask layer) 50 is formed on the semiconductor chips 10-1, 10-2 (to be specific, protection layers 32) using a photolithography method. A first resist layer 50 is formed on chip 10-1 and second resist layer 50 is formed on chip 10-2. In other words, the resist 50 is formed on regions other than the dicing lines 20. The resist is formed using a photosensitive resin containing carbon (C).

Subsequently, as shown in FIG. 4, the nitride semiconductor layer 31 is etched by dry etching using the resist 50 as a mask. In the dry etching step, an RIE (Reactive Ion Etching) method is used, for example. Wet etching may be used in the step of etching the nitride semiconductor layer 31. Due to this etching step, the nitride semiconductor layer 31 in the regions corresponding to the dicing lines 20 is removed.

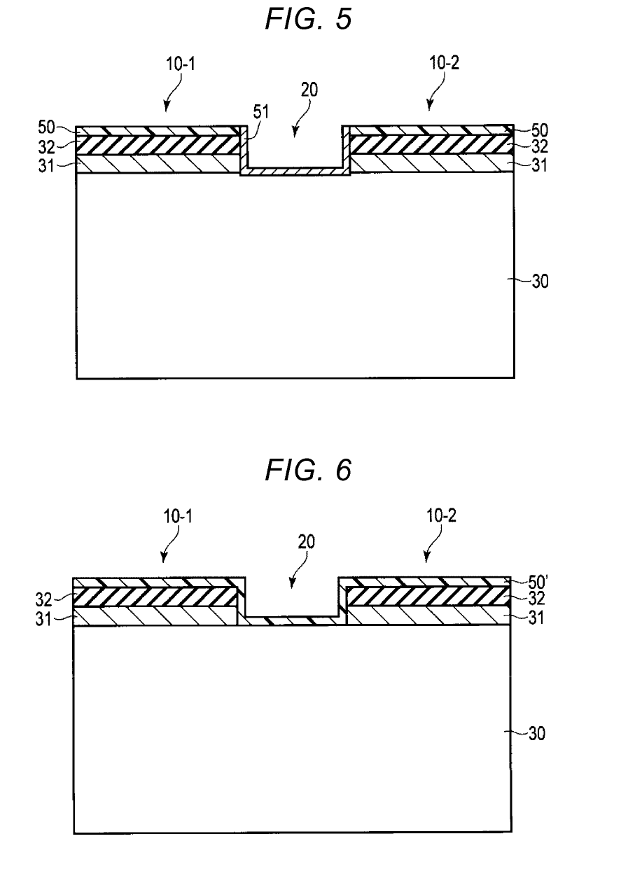

Subsequently, as shown in FIG. 5, side surfaces of the nitride semiconductor layers 31 are modified by laser processing. Specifically, a laser beam is irradiated on the opening corresponding to the dicing line 20. Then, the resist 50 is removed and, thereafter, a resist 50′ is formed so as to cover portions of the dicing line 20 as shown in FIG. 6. Alternatively, the resist 50 (the resist 50 being made of the same material as the above-mentioned resist 50 or being made of a material different from a material for forming the above-mentioned resist 50) may be formed on the existing resist 50 without removing the resist 50. Thereafter, a laser beam is irradiated to the opening portion (the opening portion where the resist exists) corresponding to the dicing line 20 to form the modified resist 50′. As a result of this, the structure shown in FIG. 5 is obtained.

By the heat generated by the laser beam, side surface portions of the nitride semiconductor layers 31, side surface portions of the protection layers 32, the substrate 30 and the resist 50 are melted and mixed with each other so that a protection layer 51 (modified layer) is formed on the side surfaces of the nitride semiconductor layers 31. In the same manner, the protection layer 51 is also formed on side surfaces of the protection layers 32 and on the substrate 30 by the heat generated by the laser beam. Plasma processing may be used in the step of modifying the side surfaces of the nitride semiconductor layers 31. “Modifying” means not only bringing a change in characteristics of the layer while containing the same contents (densification or the like) but also making the layer having the different composition by mixing a substance different from the contents of the layer into the layer.

The side surfaces of the nitride semiconductor layers 31 may be also modified by using plasma processing. Also in this case, the modifying step may be performed by using the resist 50 without removing the resist 50. Further, by taking into account the physical resistance of the resist 50 against plasma, a mask may be formed by coating a new resist (being made of the same material as the above-mentioned resist 50 or being made of a material different from the material for forming the above-mentioned resist 50).

The protection layer 51 contains a mixture containing gallium (Ga) and silicon (Si). Further, the protection layer 51 may contain at least one element selected from a group consisting of carbon (C), nitrogen (N) and oxygen (O). The protection layer 51 may contain only carbon (C). Carbon (C) is an element contained in the resist 50. Nitrogen (N) is an element contained in the nitride semiconductor layer 31, or an element contained in a surrounding environment, i.e., it may be introduced into the plasma as a gas. Oxygen (O) is an element contained in a surrounding environment in laser processing, i.e., it may be introduced into the plasma as a gas, or an element contained in a configuring material of the semiconductor device 1.

The protection layer 51 includes the following configurations (1) to (5).

(1) The protection layer 51 is densified by carbon (C).
(2) The protection layer 51 contains silicon (Si) in a surface thereof as a result of laser processing.
(3) The protection layer 51 contains silicon (Si) in the inside thereof as a result of laser processing or by diffusion.
(4) The protection layer 51 contains gallium (Ga) in a surface thereof as a result of laser processing.
(5) The protection layer 51 contains gallium (Ga) in the inside thereof as a result of laser processing or by diffusion.

In the configuration (2) and the configuration (4), the concentration of silicon (Si) or gallium (Ga) may have a gradient of concentration of silicon or gallium which increases in the protection layer 51 inwardly from a surface of the protection layer 51. In the configuration (3) and the configuration (5), the concentration of silicon (Si) or gallium (Ga) in the protection layer 51 may have a concentration gradient which decreases in the direction of the outer surface of the protection layer 51 from the interface location of the protective layer 51 with the substrate 30 and the nitride semiconductor layer 31. In the configuration (4) and the configuration (5), there may be a case where although gallium (Ga) is contained in regions of the protection layer 51 which are in contact with the side surfaces of the nitride semiconductor layers 31 exposed to the opening for the dicing lines 20, gallium (Ga) is not contained in regions of the protection layer 51 which are in contact with the side surfaces of the protection layers 32.

Subsequently, as shown in FIG. 7, for example, the semiconductor device 1 is diced along the dicing lines 20 by performing blade dicing, thereby dividing the semiconductor device 1 into the plurality of semiconductor chips 10. As a result of such dicing, the semiconductor chips 10-1, 10-2 are separated from each other with a cutting region 52 formed therebetween. Other dicing methods such as laser dicing may be used in this dicing step.

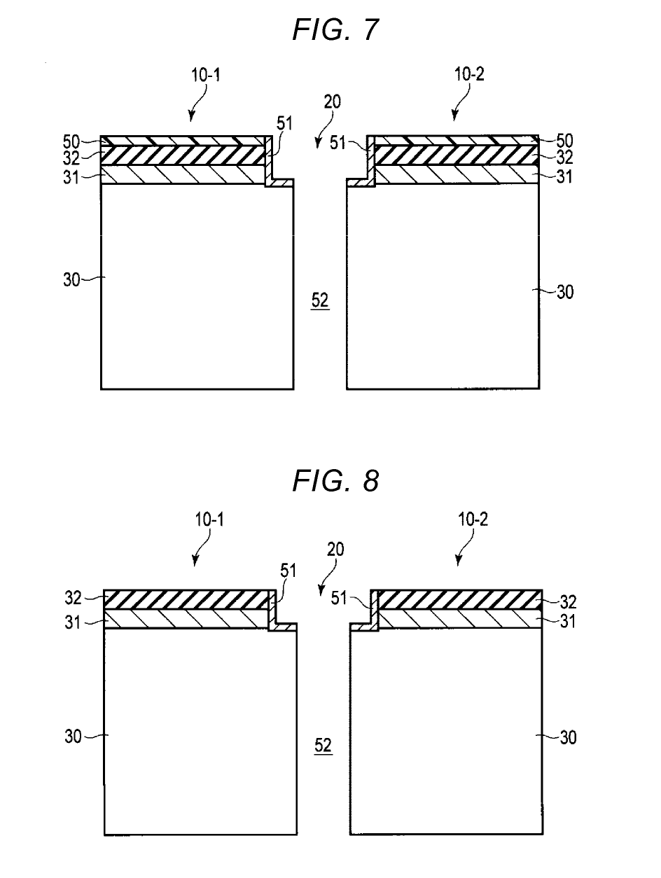

Subsequently, as shown in FIG. 8, the resist layers 50 are removed. Upon removing the resist layers 50, the protection layers 51 remain on the side surfaces of the nitride semiconductor layers 31 and the side surfaces of the protection layers 32, as well as the portion of the substrate extending outwardly from the side surfaces of the semiconductor layer 31 and the protective layer 32.

### [1-3] Advantageous Effect of First Embodiment

As has been described in detail heretofore, in the first embodiment, the nitride semiconductor layers 31 in regions corresponding to the dicing lines 20 are removed by dry etching or wet etching. Subsequently, the side surfaces of the nitride semiconductor layers 31 are modified by performing laser processing or plasma processing. Thereafter, for example, the semiconductor device 1 is divided into a plurality of semiconductor chips 10 by blade dicing along the dicing lines 20.

According to the first embodiment, the side surfaces of the nitride semiconductor layers 31 which correspond to the dicing lines 20 are covered with the protection layer 51. Accordingly, in manufacturing steps performed after the dicing step, the intrusion of water or moisture or the like into the inside of the nitride semiconductor layer 31 from the side surface of the semiconductor chip 10 may be suppressed. It is also possible to suppress water, moisture or the like from intruding into the inside of the nitride semiconductor layer 31 from a package made of a mold resin or the like which covers the semiconductor chip 10 after the semiconductor chip 10 is packaged.

Accordingly, the deterioration of the nitride semiconductor layer 31, particularly, the deterioration of the electric characteristics of the nitride semiconductor layer 31 may be suppressed. Finally, the deterioration of the semiconductor chip 10 caused by water, moisture or the like may be suppressed. Further, the occurrence of a defect in the semiconductor chip 10 may be suppressed and hence, the lowering of a yield rate may be suppressed.

Further, the semiconductor device 1 is diced after the nitride semiconductor layers 31 extending across the regions corresponding to the dicing lines 20 are removed. Accordingly, it is possible to prevent a blade which is used during blade dicing from being in direct contact with the nitride semiconductor layers 31. Accordingly, the occurrence of chipping or cracks in the nitride semiconductor layers 31 may be suppressed.

### Second Embodiment

A second embodiment is another exemplary example of forming a modified protection layer on side surfaces of nitride semiconductor layers 31. The second embodiment is characterized in that a step of etching the nitride semiconductor layers 31 and a step of modifying the nitride semiconductor layers 31 are performed simultaneously (in the same step).

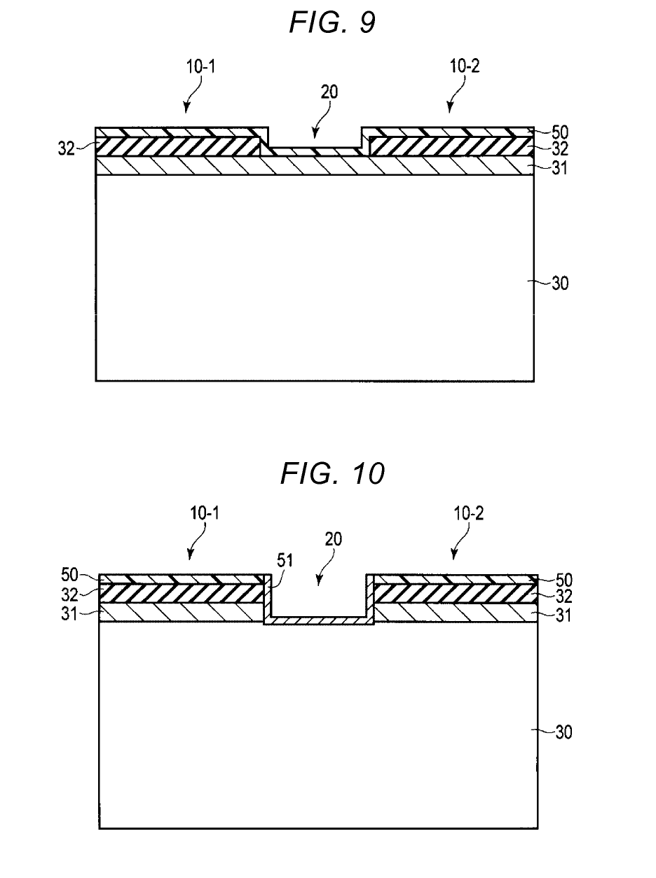

Hereinafter, a method of manufacturing a semiconductor device 1 according to the second embodiment is described by reference to FIG. 9 and FIG. 10.

First, as shown in FIG. 9, a resist 50 is formed on the whole surface of the semiconductor device 1. The resist 50 is a protection layer provided for preventing deposits formed in a laser grooving step from adhering to upper surfaces of semiconductor chips 10 and also for removing such deposit when the resist is removed.

Subsequently, as shown in FIG. 10, the nitride semiconductor layer 31 corresponding to a dicing line 20 is removed by performing laser ablation to form a groove. In this step of removing the nitride semiconductor layer 31 by the heat of a laser beam, side surface portions of the nitride semiconductor layers 31, side surface portions of protection layers 32, the adjacent exposed surface of the substrate 30 and the resist 50 are melted and mixed with each other so that a protection layer 51 (modified layer) is formed on the side surfaces of the nitride semiconductor layers 31. In the same manner, the protection layer 51 is also formed on side surfaces of the protection layers 32 and the substrate 30 by the heat of the laser beam.

Plasma etching may be used in the step of removing the nitride semiconductor layers 31. The side surfaces of the nitride semiconductor layers 31 may be also modified by the plasma etching. In this case, in the same manner as the step described by reference to FIG. 3, regions other than the dicing lines 20 are covered with additional resist and, thereafter, plasma etching is performed.

The composition of the protection layer 51 is the same as the composition of the protection layer 51 in the first embodiment. Further, in the same manner as the first embodiment, the protection layer 51 according to this embodiment has the following configurations (1) to (5).

(1) The protection layer 51 is densified carbon (C).
(2) The protection layer 51 contains silicon (Si) in a surface thereof as a result of laser processing.
(3) The protection layer 51 contains silicon (Si) in the inside thereof as a result of laser processing or by diffusion.
(4) The protection layer 51 contains gallium (Ga) in a surface thereof as a result of laser processing.
(5) The protection layer 51 contains gallium (Ga) in the inside thereof as a result of laser processing or by diffusion.

In the configuration (2) and the configuration (4), the concentration of silicon (Si) or gallium (Ga) may have a gradient of concentration of silicon or gallium which increases in the protection layer 51 inwardly from a surface of the protection layer 51. In the configuration (3) and the configuration (5), the concentration of silicon (Si) or gallium (Ga) in the protection layer 51 may have a concentration gradient which decreases in the direction of the outer surface of the protection layer 51 from the interface location of the protective layer 51 with the substrate 30 and the nitride semiconductor layer 31. In the configuration (4) and the configuration (5), there may be a case where although gallium (Ga) is contained in regions of the protection layer 51 which are in contact with the side surfaces of the nitride semiconductor layers 31 exposed to the opening for the dicing lines 20, gallium (Ga) is not contained in regions of the protection layer 51 which are in contact with the side surfaces of the protection layers 32.

The subsequent manufacturing steps are the same as the corresponding manufacturing steps according to the first embodiment.

As has been described heretofore in detail, according to the second embodiment, in the same manner as the first embodiment, the protection layer 51 is formed on the side surfaces of the nitride semiconductor layers 31. Due to the formation of the protection layer 51 on the side surfaces of the nitride semiconductor layers 31, in the second embodiment, it is possible to obtain the same advantageous effects as in the first embodiment.

In the second embodiment, the step of etching the nitride semiconductor layers 31 and the step of modifying the nitride semiconductor layers 31 are performed simultaneously (in the same step). Accordingly, the number of manufacturing steps may be reduced compared with the first embodiment and hence, a manufacturing cost may be reduced.

### Third Embodiment

In a third embodiment, an opening is formed in a nitride semiconductor layer 31 in a region corresponding to a dicing line 20 and, thereafter, side surfaces of the nitride semiconductor layer 31 are covered with protection layers 54. As a result of the presence of the protection layers 54, the intrusion of water or the like from the side surfaces of the nitride semiconductor layers 31 may be suppressed.

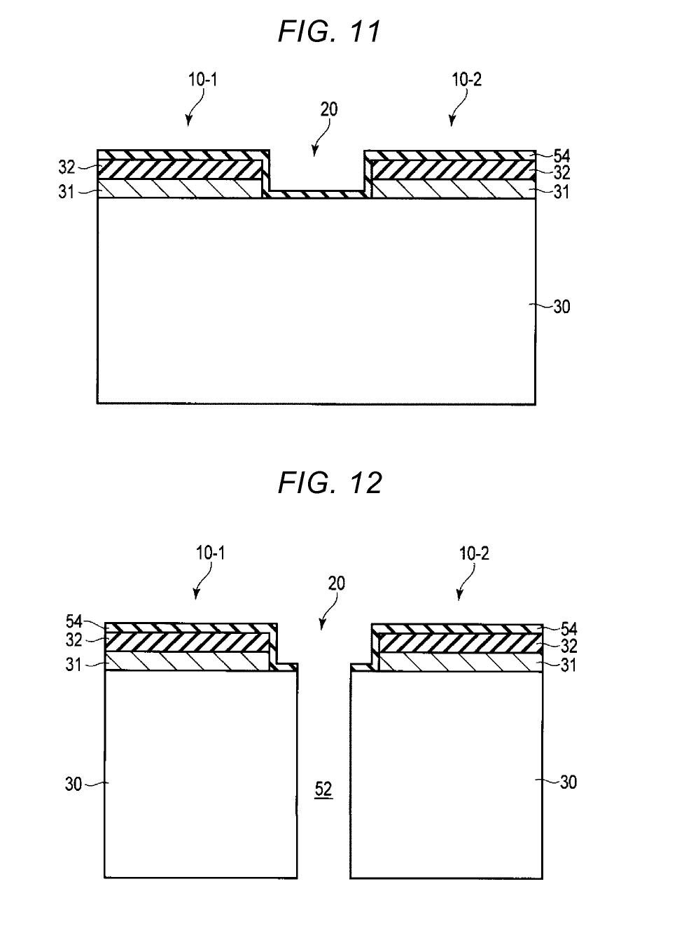

Hereinafter, a method of manufacturing a semiconductor device 1 according to the third embodiment is described with reference to FIG. 11 and FIG. 12. Manufacturing steps in the third embodiment are the same as manufacturing steps in the first embodiment as shown in FIG. 4. In the third embodiment, however, the resist 50 is removed after the manufacturing step shown in FIG. 4 is finished.

Subsequently, as shown in FIG. 11, the protection layer 54 made of an insulation material is formed on the whole surface of the semiconductor device 1 using a CVD (Chemical Vapor Deposition) method, for example. As a material for forming the protection layer 54, for example, silicon oxide (SiO₂), silicon nitride (SiN) or the like is used. Accordingly, the protection layer 54 is formed on a plurality of semiconductor chips 10, side surfaces of the nitride semiconductor layers 31 and side surfaces of protection layers 32, and regions of a substrate 30 corresponding to the dicing lines 20.

Subsequently, as shown in FIG. 12, the semiconductor device 1 is cut along the dicing line 20, for example, by blade dicing, thereby dividing the semiconductor device 1 into a plurality of semiconductor chips 10. By such dicing, semiconductor chips 10-1, 10-2 are separated from each other with a cutting region 52 formed therebetween. Other dicing methods such as laser dicing may be used in this dicing step.

The protection layer 54 formed on the semiconductor chips 10 may be removed before the dicing step, or the protection layer 54 formed on the semiconductor chips 10 may not used to be removed. When the protection layer 54 remains without being removed, electrode pads exposed on upper surfaces of the semiconductor chips 10 are respectively formed again through openings formed in the protective layer 54.

As has been described heretofore in detail, according to the third embodiment, the side surfaces of the nitride semiconductor layers 31 may be covered with the protection layer 54 made of an insulation material. Accordingly, in the third embodiment, it is possible to obtain the same advantageous effects as the first embodiment.

In the above-mentioned respective embodiments, the semiconductor device where the nitride semiconductor layer is formed on the substrate is used. However, the present invention is not limited to such a semiconductor device. The respective embodiments may be also applicable to a semiconductor device where an epitaxial layer made of a compound semiconductor different from a material for forming the substrate is formed on the substrate.

In this disclosure, “stack” means not only a state where layers are made to overlap with each other in a contact manner but also a state where layers are made to overlap with each other with another layer interposed therebetween. Further, “provided on” means not only a state where a layer is directly provided on a layer but also a state where a layer is provided on a layer with another layer interposed therebetween.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a substrate;
a nitride semiconductor layer provided on the substrate; and
a first protection layer comprising carbon, covering a side surface of the nitride semiconductor layer.

2. The semiconductor device according to claim 1, wherein the first protection layer further comprises at least one element selected from a group consisting of gallium and silicon.

3. The semiconductor device according to claim 1, wherein the first protection layer further comprises at least one element selected from a group consisting of nitrogen and oxygen.

4. The semiconductor device according to claim 1, wherein the first protection layer comprises silicon at a surface thereof or in the inside thereof.

5. The semiconductor device according to claim 1, wherein the first protection layer comprises gallium at a surface thereof, or therewithin.

6. The semiconductor device according to claim 1, wherein the first protection layer is provided on a region of the substrate where the nitride semiconductor layer is not provided.

7. The semiconductor device according to claim 1, further comprising:
a second protection layer provided on the nitride semiconductor layer comprising an insulation material,
wherein the first protection layer is also provided on a side surface of the second protection layer.

8. The semiconductor device according to claim 1, wherein the side surface of the nitride semiconductor layer is disposed inwardly of the side surface of the substrate.

9. The semiconductor device according to claim 1, wherein the substrate comprises silicon, and
the nitride semiconductor layer comprises gallium nitride.

10. A method of manufacturing a semiconductor device including first and second semiconductor chips that respectively include a nitride semiconductor layer and are disposed with a gap therebetween, the method comprising:
forming first and second masks on the first and second semiconductor chips, respectively;
etching the portion of the nitride semiconductor layer provided in the gap between the first and second semiconductor chips to form side surfaces on the nitride semiconductor layers, the side surfaces facing the gap between the first and second semiconductor chips;
modifying side surfaces of the nitride semiconductor layers by a laser beam; and
singulating the first and second semiconductor chips facing the gap.

11. The method of manufacturing a semiconductor device according to claim 10, wherein the etching and the modifying are performed in the same step.

12. The method according to claim 10, further comprising:
after etching the portion of the nitride semiconductor layer provided in the gap, forming a protective film layer over the side surfaces of the nitride semiconductor layer facing the gap between the first and second semiconductor chips.

13. The method according to claim 12, further comprising forming the nitride semiconductor layer on a silicon substrate.

14. The method according to claim 10, wherein etching the portion of the nitride semiconductor layer provided in the gap and modifying side surfaces of the nitride semiconductor layers by a laser beam are performed simultaneously.

15. The method according to claim 14, further including:
providing a protective layer in the gap prior to etching the portion of the nitride semiconductor layer provided in the gap; and
modifying side surfaces of the nitride semiconductor layers with a laser beam.

16. The method according to claim 10, wherein a protective layer is provided on the side surfaces of the nitride semiconductor layer facing the gap as a result of the modification of the nitride semiconductor layer with a laser beam.

17. The method according to claim 16, wherein the protective layer comprises carbon.

18. A semiconductor device, comprising:
a substrate having an upper surface and at least one side surface;
a nitride semiconductor layer provided on the upper surface of the substrate, a side surface of the nitride semiconductor layer offset from the side surface of the substrate such that a portion of the upper surface of the substrate extends outwardly from the side surface of the nitride semiconductor layer; and
a protective layer disposed on the upper surface of the substrate adjacent to the side surface of the substrate and on the side surface of the nitride semiconductor layer, the protective layer comprising at least an element of the nitride semiconductor layer and an element of the substrate.

19. The semiconductor device of claim 18, wherein the protective layer further comprises carbon.

20. The semiconductor device of claim 18, wherein the protective layer further comprises silicon.
